(19) United States
(12) Patent Application Publication
(10) Pub. No.: US 2017/0253972 A1
(43) Pub. Date: Sep. 7, 2017

(54) SUBSTRATE PROCESSING APPARATUS

(71) Applicants: TOKYO ELECTRON LIMITED, Tokyo (JP); TOHOKU TECHNO ARCH CO., LTD., Miyagi (JP)

(72) Inventors: Kiyotaka ISHIBASHI, Miyagi (JP); Yoshiyuki KIKUCHI, Miyagi (JP); Seiji SAMUKAWA, Miyagi (JP)

(73) Assignees: TOKYO ELECTRON LIMITED, Tokyo (JP); TOHOKU TECHNO ARCH CO., LTD., Miyagi (JP)

(21) Appl. No.: 15/600,467

(22) Filed: May 19, 2017

Related U.S. Application Data
(62) Division of application No. 14/597,929, filed on Jan. 15, 2015.

(30) Foreign Application Priority Data
Jan. 16, 2014 (JP) 2014-005782

(51) Int. Cl. C23C 16/455; C23C 16/04; C23C 16/511; C23C 16/458; H01J 37/32

(52) U.S. Cl. CPC C23C 16/45591; C23C 16/4584; H01J 37/32422; C23C 16/511; H01J 37/32357; C23C 16/045

(57) ABSTRACT

Provided is a substrate processing including: a plasma generation source configured to generate the plasma within the processing container; a substrate holding mechanism configured to hold the substrate within the processing container; a separation plate disposed between the plasma generation source and the substrate holding mechanism and having a plurality of openings formed therein, in which the plurality of openings are configured to neutralize the plasma generated in the plasma generation source so as to form neutral particles, and to irradiate the neutral particles onto the substrate; and a directivity adjusting mechanism configured to adjust directivity of the neutral particles irradiated onto the substrate such that a plurality of peak values of an incident angle distribution of the neutral particles on the substrate are distributed at positions which are deviated from a normal direction of the substrate and located on both sides of the normal direction.

### CROSS-REFERENCE TO RELATED APPLICATIONS

This application is a divisional of U.S. patent application Ser. No. 14/597,929, filed on Jan. 15, 2015, which claims priority from Japanese Patent Application No. 2014-005782, filed on Jan. 16, 2014, with the Japan Patent Office, the disclosures of which are incorporated herein in their entireties by reference.

### TECHNICAL FIELD

The present disclosure relates to a substrate processing apparatus that processes a substrate by plasma.

### BACKGROUND

In manufacturing a semiconductor device, a film forming processing of forming various films including an insulation film on a semiconductor wafer (hereinafter, referred to as a “wafer”) or an etching processing for forming a pattern using, for example, the insulation film, is performed within a depressurized processing container provided in a substrate processing apparatus such as, for example, a plasma processing apparatus.

However, since ions or ultraviolet light are irradiated on a wafer in, for example, a plasma CVD apparatus that performs a film formation processing on the wafer, the wafer or a film formed thereon is damaged by the ions or ultraviolet light. Therefore, for example, Japanese Laid-Open Patent Publication No. 2005-89823 has proposed a technology in which ultraviolet light generated by plasma is blocked and ions are supplied after being converted into neutral particles so as to perform a plasma processing with less damage.

According to Japanese Laid-Open Patent Publication No. 2005-89823, a separation plate with a plurality of vertically elongated holes having a small diameter is provided between a plasma generation chamber in which plasma is generated and a substrate as an object to be processed, and a bias voltage is applied to the separation plate such that ions passing through the holes are neutralized. Further, most of the ultraviolet light is blocked by the separation plate. As a result, only the neutral particles are irradiated onto the wafer so that a substrate processing is performed with less damage.

### SUMMARY

The present disclosure provides a substrate processing apparatus that processes a substrate within a processing container by plasma. The substrate processing apparatus includes: a plasma generation source configured to generate the plasma within the processing container; a substrate holding mechanism disposed to face the plasma generation source, and configured to hold the substrate within the processing container; a separation plate disposed between the plasma generation source and the substrate holding mechanism and having a plurality of openings formed therein, the plurality of openings being configured to neutralize the plasma generated in the plasma generation source so as to form neutral particles, and to irradiate the neutral particles onto the substrate held on the substrate holding mechanism; and a directivity adjusting mechanism configured to adjust directivity of the neutral particles irradiated onto the substrate such that a plurality of peak values of an incident angle distribution of the neutral particles on the substrate held by the substrate holding mechanism are distributed at positions which are deviated from a normal direction of the substrate and located on both sides of the normal direction. The openings of the separation plate include first openings inclined with respect to a direction perpendicular to a surface of the substrate held on the substrate holding mechanism by a predetermined angle, and second openings foamed in linear symmetry with respect to an axis perpendicular to the surface of the separation plate, and the first openings and the second openings are formed alternately to be adjacent to each other.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a schematic vertical cross-sectional view illustrating an exemplary configuration of a substrate processing apparatus according to an exemplary embodiment.

FIG. 2 is an enlarged cross sectional view illustrating a schematic configuration of a separation plate.

FIG. 3 is an explanatory view illustrating a situation where neutral particles are irradiated onto a pattern formed on a wafer W at a predetermined incident angle.

FIG. 4 is an explanatory view illustrating a situation where neutral particles are irradiated onto a pattern formed on a wafer W at a predetermined incident angle.

FIG. 5 is an explanatory view illustrating a relationship between an aspect ratio of a pattern formed on a wafer and an incident angle of neutral particles.

FIG. 6 is an explanatory view illustrating a relationship between an aspect ratio of a pattern formed on the wafer and an incident angle of neutral particles.

FIG. 7 is an explanatory view illustrating a relationship between an aspect ratio of a patterns formed on a wafer and an angle of openings.

FIG. 8 is an explanatory view illustrating an incident angle distribution of neutral particles irradiated onto a wafer.

FIG. 9 is an explanatory view illustrating a schematic configuration in the vicinity of a separation plate according to another exemplary embodiment.

FIG. 10 is a plan view illustrating a schematic configuration of a separation plate according to another exemplary embodiment.

FIG. 11 is an explanatory view illustrating a situation where a separation plate and a wafer are inclined in relation to each other.

FIG. 12 is an explanatory view illustrating an example of an arrangement of a separation plate and wafers according to another exemplary embodiment.

FIG. 13 is a plan view illustrating an example of the arrangement of the separation plate and the wafer according to the exemplary embodiment of FIG. 12.

FIG. 14 is an explanatory view illustrating a situation where neutral particles are irradiated onto a wafer from a vertical direction.

### DETAILED DESCRIPTION

In the following detailed description, reference is made to the accompanying drawings, which form a part hereof. The illustrative embodiments described in the detailed description, drawing, and claims are not meant to be limiting. Other exemplary embodiments may be utilized, and other changes may be made without departing from the spirit or scope of the subject matter presented here.

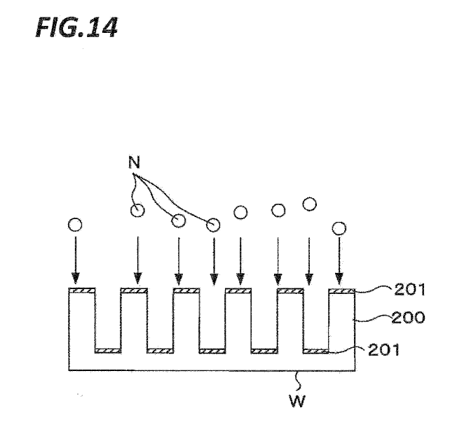

Since neutral particles have a high straight travelling property, it was difficult to uniformly process, for example, a wafer including a predetermined concave-convex pattern formed thereon. Specifically, for example, as illustrated in FIG. 14, neutral particles N that have passed through vertically elongated holes formed in a separation plate has vertically downward directivity. Thus, even if, for example, a predetermined film 201 may be formed on a top end portion or a bottom portion of a concave-convex pattern 200 formed on a wafer W, the neutral particles are not irradiated onto side surfaces of the concave-convex pattern 200. Thus, film formation is not able to be performed on the side surfaces. Accordingly, it is difficult to perform a uniform processing in a wafer plane.

The present disclosure has been made in consideration of the problems described above and intends to perform a substrate processing uniformly in a wafer plane using neutral particles.

In order to achieve the object described above, the present disclosure provides a substrate processing apparatus that processes a substrate within a processing container by plasma. The substrate processing apparatus includes: a plasma generation source configured to generate the plasma within the processing container; a substrate holding mechanism disposed to face the plasma generation source, and configured to hold the substrate within the processing container; a separation plate disposed between the plasma generation source and the substrate holding mechanism and having a plurality of openings formed therein, the plurality of openings being configured to neutralize the plasma generated in the plasma generation source so as to form neutral particles, and to irradiate the neutral particles onto the substrate held on the substrate holding mechanism; and a directivity adjusting mechanism configured to adjust directivity of the neutral particles irradiated onto the substrate such that a plurality of peak values of an incident angle distribution of the neutral particles on the substrate held by the substrate holding mechanism are distributed at positions which are deviated from a normal direction of the substrate and located on both sides of the normal direction. In addition, the openings of the separation plate include first openings inclined with respect to a direction perpendicular to a surface of the substrate held on the substrate holding mechanism by a predetermined angle, and second openings formed in linear symmetry with respect to an axis perpendicular to the surface of the separation plate, and the first openings and the second openings are formed alternately to be adjacent to each other.

The directivity adjusting mechanism may adjust the directivity of the neutral particles by rotating the substrate held on the substrate holding mechanism and the separation plate in relation to each other.

According to another aspect of the present disclosure, provided is a substrate processing apparatus that processes a substrate within a processing container by plasma. The substrate processing apparatus includes: a plasma generation source configured to generate the plasma within the processing container; a substrate holding mechanism disposed to face the plasma generation source, and configured to hold the substrate within the processing container; a separation plate disposed between the plasma generation source and the substrate holding mechanism and having a plurality of openings formed therein, the plurality of openings being configured to neutralize the plasma generated in the plasma generation source so as to form neutral particles, and to irradiate the neutral particles onto the substrate held on the substrate holding mechanism; and a directivity adjusting mechanism configured to adjust directivity of the neutral particles irradiated onto the substrate such that a plurality of peak values of an incident angle distribution of the neutral particles on the substrate held by the substrate holding mechanism are distributed at positions which are deviated from a normal direction of the substrate and located on both sides of the normal direction. The separation plate is divided into a plurality of sections and the openings are formed in each section to be inclined with respect to the vertical direction by a predetermined angle, and the directivity adjusting mechanism adjusts the directivity of the neutral particles by rotating the substrate held on the substrate holding mechanism and the separation plate in relation to each other.

The directivity adjusting mechanism may adjust the directivity of the neutral particles such that the peak values in the incident angle distribution of the neutral particles are distributed in 2n-fold symmetry (n is an integer of 1 or more).

According to the present disclosure, it is possible to perform a uniform processing in a wafer plane using neutral particles.

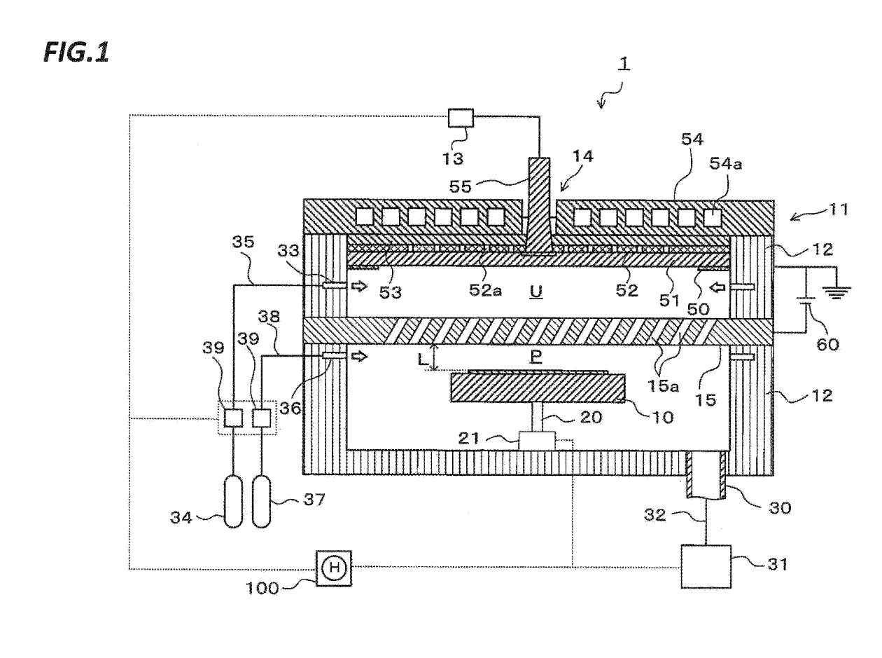

Hereinafter, descriptions will be made on an exemplary embodiment of the present disclosure with reference to the accompanying drawings. FIG. 1 is a vertical cross-sectional view illustrating a schematic configuration of a substrate processing apparatus 1 according to an exemplary embodiment of the present disclosure. In the meantime, the substrate processing apparatus 1 in the present exemplary embodiment is, for example, a plasma processing apparatus which converts a processing gas supplied into the apparatus into plasma by microwaves and performs a plasma processing on a wafer W.

The substrate processing apparatus 1 includes a substantially cylindrical processing container 11 which is provided with a wafer chuck 10 configured to hold the wafer. The processing container 11 includes a body 12 of which top portion is opened to correspond to the wafer W on the wafer chuck 10, and a microwave supply unit 14 which closes the opening formed on the body 12 and supplies microwaves of, for example, 2.45 GHz, generated from the microwave generation source 13 into the processing container 1. Further, a separation plate 15 is provided between the microwave supply unit 14 and the wafer chuck 10 to separate the inside of the processing container 11 into a plasma generation chamber U of the microwave supply unit 14 side and a processing chamber P of the wafer chuck 10 side.

The wafer chuck 10 has a horizontal top surface. Further, an electrode (not illustrated) is provided inside the wafer chuck 10. Accordingly, the wafer W may be attracted and held horizontally on the top surface of the wafer chuck 10 by attracting the wafer W by an electrostatic force generated by applying a DC voltage to the electrode.

The wafer chuck 10 is provided with a chuck driving mechanism 21 including, for example, a motor, through a rotation shaft 20 and may be rotated at a predetermined speed by the chuck driving mechanism 21.

An exhaust port 30 which evacuates the inside of the processing container 11 is formed in the bottom portion of the body 12 of the processing container 11. The exhaust port 30 is connected with an exhaust pipe 32 which communicates with an exhaust mechanism 31 such as, for example, a vacuum pump. Accordingly, atmosphere inside of the processing container 11 may be exhausted through the exhaust port 30 by the exhaust mechanism 31 to depressurize the inside of the processing container 11 to a predetermined degree of vacuum.

A first gas supply port 33 for supplying a predetermined gas into the plasma generation chamber U of the processing container 11 is formed on an inner peripheral surface of the body 12 of the processing container 11 and above the separation plate 15. A plurality first gas supply ports 33 are formed, for example, at a plurality of sites along the inner peripheral surface of the processing container 11. The first gas supply ports 33 are connected with a gas supply pipe 35 which communicates with, for example, a first gas supply unit 34 provided outside the processing container 11. For example, a noble gas for plasma generation is supplied from the first gas supply unit 34. Further, a plurality of second gas supply ports 36 for supplying a predetermined gas into the processing chamber P are also formed on the inner peripheral surface, below the separation plate 15 in the body 12 of the processing container 11 and above the wafer chuck 10. The second gas supply port 36 is connected with a gas supply pipe 38 which communicates with, for example, a second gas supply unit 37 provided outside the processing container 11. For example, a processing gas for film formation on the wafer W is supplied from the second gas supply unit 37. Flow rate adjusting units 39, 39 each including a valve or a mass flow controller are provided in the gas supply pipes 35, 38, respectively, and the flow rate of the gas supplied from each of the gas supply ports 33, 36 is controlled by each of the flow rate adjusting units 39, 39.

The microwave supply unit 14 includes, for example, a microwave transmission plate 51 supported on a supporting member 50 provided to project into the inside of the body 12a through a sealing material (not illustrated), such as, for example, an O ring for securing air tightness, a slot plate 52 disposed on the top surface of the microwave transmission plate 51 and functioning as an antenna, a dielectric plate 53 disposed on the top surface of the slot plate 52 and functioning as a wave retardation plate, and a metallic plate 54 disposed on the, top surface of the dielectric plate 53. All the microwave transmission plate 51, the slot plate 52, the dielectric plate 53, and the plate 54 have a substantially disk shape. Further, the microwave transmission plate 51 and the dielectric plate 53 are made of a dielectric material such as, for example, quartz, alumina, or aluminum nitride. The slot plate 52 is made of a conductive material such as, for example, copper, aluminum, or nickel, and is planar antenna member of so-called a radial line slot antenna type in which a plurality of slots 52a are concentrically formed. Each slot 52a is substantially rectangular in a plan view and penetrates the slot plate 52 in the vertical direction. A refrigerant passage 54a in which the refrigerant flows is formed within the plate 54 to suppress increase of the temperature of the plate 54 by heat at the time of plasma processing.

A coaxial waveguide 55 is connected to the central part of the microwave supply unit 14 and the microwave generation source 13 is connected with the coaxial waveguide 55. The microwaves generated in the microwave generation source 13 are introduced into the microwave supply unit 14 through the coaxial waveguide 55 and irradiated into the plasma generation chamber U of the processing container 11 through the slot plate 52 and the microwave transmission plate 51. When the microwaves are irradiated into the plasma generation chamber U, the noble gas of the plasma generation chamber U is excited to generate plasma. In this case, the plasma generation chamber U functions as a plasma generation source which generates plasma in the processing container 11.

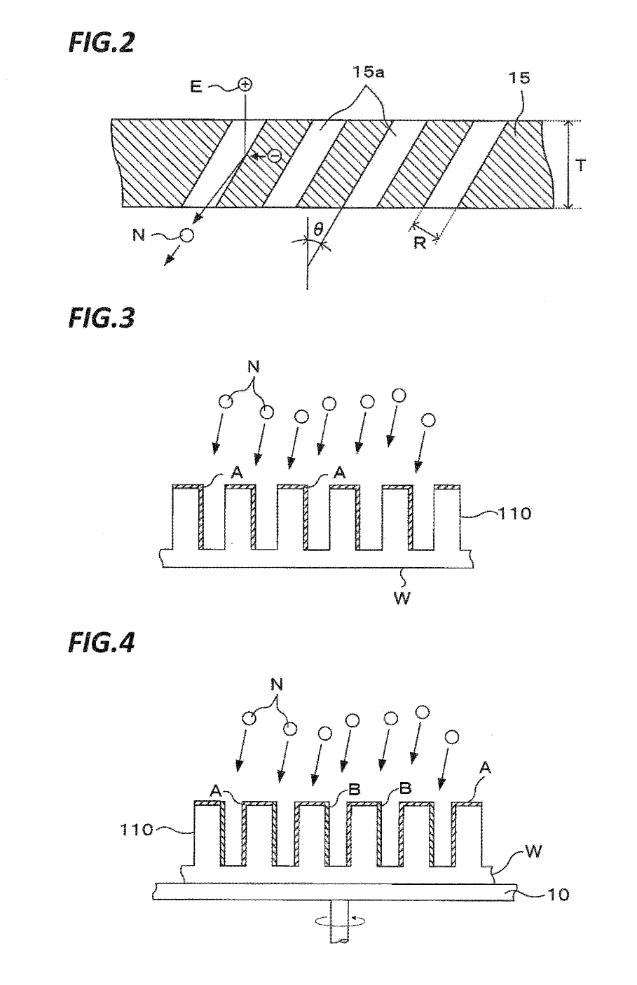

Next, descriptions will be made on a configuration of the separation plate 15 along with the principle of the present disclosure. The separation plate 15 is formed with a substantially disk shape and made of a conductive material such as, for example, carbon, silicon, or aluminum, and is provided parallel to the wafer W held on the wafer chuck 10 as illustrated in FIG. 1. A plurality of openings 15a which penetrate the separation plate 15 in the thickness direction are formed on the separation plate 15. The openings 15a are formed to be inclined with respect to the vertical direction by a predetermined angle θ, for example, as illustrated in FIG. 2. Accordingly, when positive ions such as, for example, charged particles E generated by plasma of the plasma generation chamber U, are incident on the openings 15a from above the separation plate 15, the charged particles E impinge onto the separation plate 15 and travel obliquely downward. Setting of the angle θ will be described later.

In the meantime, an aspect ratio, which is a ratio between the thickness T of the separation plate 15 and the diameter R of the openings 15a, may be set to a range between about 5 and about 20, and is set to, for example, about 10 in the present exemplary embodiment. An opening ratio, which is a ratio of a total area of the openings 15 to a surface area of the separation plate 15, may be set to a range between about 5% and about 10% and is set to, for example, about 8% in the present exemplary embodiment. In the meantime, the aspect ratio and the opening ratio of the separation plate 15 are set such that UV light directed from the plasma generation chamber U to the processing chamber P is blocked by the separation plate 15. Further, the aspect ratio and opening ratio of the separation plate 15 are set such that a pressure difference between the processing chamber P and the plasma generation chamber U may be maintained at a predetermined value in order to prevent the processing gas from being introduced into the plasma generation chamber U from the processing chamber P.

Further, the separation plate 15 is connected with a DC power supply 60 as illustrated in FIG. 1 so that a predetermined DC voltage is applied to the separation plate 15. Accordingly, the charged particles E, which have impinged on the separation plate 15 in the openings 15a, receive electrons from the separation plate 15 to be electrically neutralized to be neutral particles N, and the neutral particles N are discharged from the openings 15a toward the processing chamber P. Accordingly, the separation plate 15 also functions as a directivity adjusting mechanism which generates the neutral particles N by neutralizing the charged particles E generated by plasma of the plasma generation chamber U and adjusts directivity to cause the neutral particles N to travel obliquely downward.

For example, in a case where a wafer W, which is formed with a concave-convex pattern 110 such as, for example, a so-called line and space pattern illustrated in FIG. 3, is processed, when the directivity of neutral particles N is adjusted so as to cause the neutral particles N to travel obliquely downward using the separation plate 15, the neutral particles N may be irradiated onto the side surfaces of the pattern 110 as well as the top surface of the pattern 110. However, since the neutral particles N have a high straight travelling property, the neutral particles N travelling obliquely downward are irradiated only onto an area A formed by adding the top surface and one side surface of the pattern 110 without being irradiated onto the other side surface of the pattern 110. Therefore, the entire surface of the pattern 110 cannot be uniformly processed merely by causing the neutral particles N to have directivity in an oblique direction.

Therefore, the inventors have reviewed a method of irradiating the neutral particles N onto the entire surface of the pattern 110 on the wafer W and considered that when a position of a relative rotational direction of the separation plate 15 having openings 15a inclined with respect to, for example, the vertical direction by the predetermined angle θ and the wafer W is rotated about, for example, an axis which is perpendicular to the surface of wafer W, by 180 degrees, the neutral particles N may also be irradiated onto the side opposite to the area A. Accordingly, in the present exemplary embodiment, the wafer chuck 10 of the substrate processing apparatus 1 is configured to be capable of being rotated and the wafer W is adapted to be rotated in relation to the separation plate 15. In this case, when the openings 15a inclined by the predetermined angle θ are formed and the wafer W is rotated by the wafer chuck 10, the directivity of the neutral particles N irradiated onto the wafer W may be adjusted. Thus, the openings 15a inclined by the predetermined angle θ and the wafer chuck 10 function as the directivity adjusting mechanism in the present exemplary embodiment.

In this case, as illustrated in FIG. 3, when the neutral particles N are irradiated onto the wafer W in a certain direction and then the wafer chuck 10 is rotated by 180 degrees, the neutral particles N may be irradiated onto the top surface of the pattern 110 and an area B which located at a side opposite to the area A by interposing the pattern 110 between the area A and the area B4 as illustrated in FIG. 4. In this way, the neutral particles N are irradiated onto the entire surface of the pattern 110 on the wafer W.

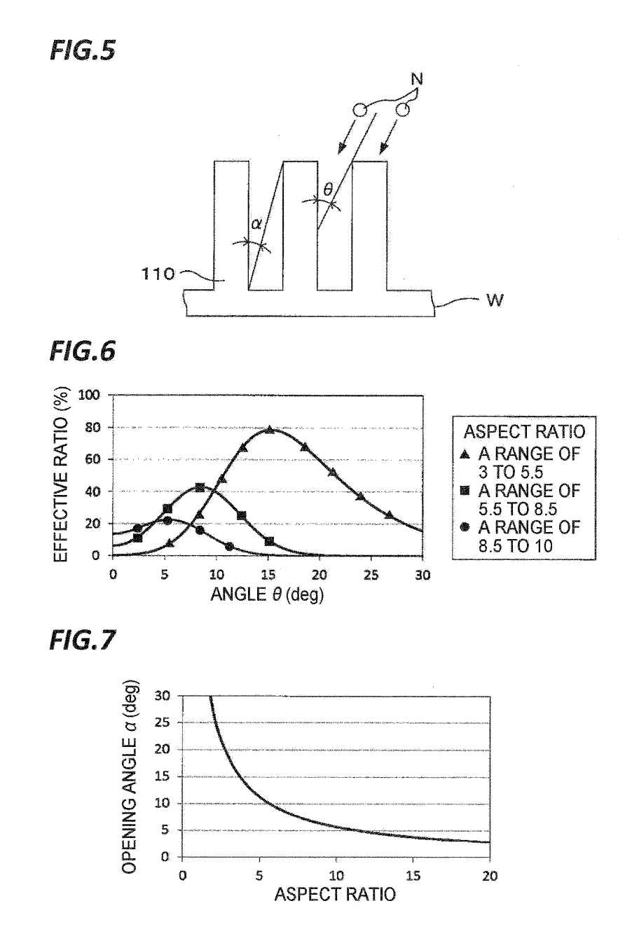

In the meantime, when the angle θ between the openings 15a and the vertical axis is made larger, an angle when the charged particles E impinge onto the separation plate 15 in the openings 15a becomes larger and thus energy attenuation becomes larger. Further, when the angle θ is made larger, the neutral particles N are unable to reach the bottom surface of the pattern 110 and the side surfaces in the vicinity of the bottom surface thereof the pattern 110 when a processing on a trench-shaped pattern 110 having a high aspect ratio is performed, for example, as illustrated in FIG. 5. Therefore, the angle θ may be made smaller, but when the angle θ is made too small, the incident angle to the side surfaces of the pattern 110 becomes smaller and thus, it is unable to give sufficient energy to the side surfaces of the pattern 110. Accordingly, the angle θ of the openings 15a is suitably set based on the aspect ratio of the pattern 110 formed on the wafer W to be processed or energy required for processing the side surfaces of the pattern 110. In the meantime, it has been found by the inventors that the angle θ of the openings 15a may be set to about 4 degrees to 28 degrees.

Descriptions will be made further on setting of the angle θ of the openings 15a of the separation plate 15. Prior to setting the angle θ of the openings 15a, the inventors investigated that what percentage of the neutral particles arrive at the side surfaces of the pattern 110 by irradiating the neutral particles N onto the pattern 110 having the predetermined aspect ratio through the openings 15a having an angle set to the predetermined angle θ. The result is illustrated in FIG. 6. The horizontal axis of FIG. 6 indicates the angle θ of the openings 15a and an “effective ratio” indicated in the vertical axis indicates a ratio of the neutral particles N actually arriving at the side surfaces of the pattern 110 among the neutral particles N irradiated from the openings 15a. Further, in FIG. 6, a graph represented by symbol “Δ” indicates a result for a case where an aspect ratio of a concave-convex portion of the pattern 110 is in a range of 3 to 5.5, a graph represented by symbol “□” indicates a result for a case where an aspect ratio of a concave-convex portion of the pattern 110 is in a range of 5.5 to 8.5, and a graph represented by symbol “∘” indicates a result for a case where an aspect ratio of a concave-convex portion of the pattern 110 is in a range of 8.5 to 10.

According to the inventors, it has been found that it is desirable that the secured effective ratio of the neutral particles N in the side surfaces of the pattern 110 is about 20% or more in the wafer processing. Accordingly, as can be seen from the results of FIG. 6, when the aspect ratio is in the range of 3 and 5.5, the angle θ of the openings 15a may be in the range of about 8 degrees to about 28 degrees, when the aspect ratio is in the range of 5.5 to 8.5, the angle θ of the openings 15a may be in the range of, about 4 degrees to about 13 degrees, and when the aspect ratio is in the range of 8.5 to 10, the angle θ of the openings 15a may be in the range of about 4 degrees to about 7 degrees. Also, since the aspect ratio of the concave-convex portion of the pattern 110 is different depending on a structure of the device, but normally is in the range of 3 to 10, the angle θ of the openings 15a may be in the range of about 4 degrees to about 28 degrees, as described above.

In the meantime, an opening angle α formed by a side wall of the trench-shaped pattern 110 and a diagonal line extending between the top end portion of the trench-shaped pattern 110 and the bottom portion located diagonally to the top end of the trench has an inversely proportional relationship with the aspect ratio of the concave-convex portion of the trench shaped pattern 110, as illustrated in FIG. 7. Also, it can be seen from the results of FIG. 6 and the relationship of FIG. 7 that the angle θ of the openings 15a has approximately the same range as the opening angle α corresponding to the aspect ratio of the pattern 110.

From the viewpoint of suppressing the attenuation in energy of the neutral particles N irradiated onto the wafer W, the distance L between the top surface of the wafer W and the bottom surface of the separation plate 15 may be set not to be more than a mean free path of the neutral particles N in the processing chamber.

The substrate processing apparatus 1 described above is provided with a control device 100. The control device 100 is constituted by a computer provided with, for example, a CPU or a memory, and a substrate processing in the substrate processing apparatus 1 is executed by causing the control device 100 to execute, for example, a program stored in the memory. In the meantime, various programs for implementing a substrate processing or substrate conveyance in the substrate processing apparatus 1 have been stored in a computer readable storage medium H such as, for example, a hard disk (HD), a flexible disk (FD), a compact disk (CD), a magneto-optical disk (MO), or a memory card, and the programs installed in the control device 100 from the storage medium H are utilized.

The substrate processing apparatus 1 according to the present exemplary embodiment is configured as described above, and next, descriptions will be made on a processing of a wafer W in the substrate processing apparatus 1.

In the wafer processing, first, the wafer W is carried into the processing container 11 and held on the wafer chuck 10. On the wafer W, for example, a concave-convex pattern such as, for example, a trench shaped pattern 110 is formed in advance, as illustrated in FIG. 3.

When the wafer W is held on the wafer chuck 10, the inside of the processing container 11 is evacuated by the exhaust mechanism 31 to be depressurized to a predetermined pressure. Subsequently, a noble gas for plasma generation is supplied from the first gas supply unit 34 to the plasma generation chamber U, microwaves are supplied from the microwave supply unit 14 into the processing container 11 at a predetermined pressure, and an electric field is formed on the bottom surface of the microwave transmission plate 51. In this way, the noble gas within the plasma generation chamber U is excited to generate plasma.

Charged particles E or radicals in the plasma generated within the plasma generation chamber U are supplied to the processing chamber P side through the openings 15a of the separation plate 15. In this case, a predetermined DC voltage is applied to the separation plate 15 by the DC power supply 60, the charged particles E having impinged onto, for example, the separation plate 15 in the openings 15a receive electrons from the separation plate 15 to be electrically neutralized to be neutral particles N, and the neutral particles N are supplied to the processing chamber P. Further, ultraviolet light irradiated from the plasma of the plasma generation chamber U is blocked by the separation plate 15.

In parallel with the supply of the microwaves from the microwave supply unit 14, a source gas for forming a predetermined film on the wafer W is supplied from the second gas supply unit 37 into the processing chamber P. In the processing chamber P, the processing gas is excited by the neutral particles N supplied from the separation plate 15. In this way, a predetermined film is formed on the wafer W using the source gas serving as a film-forming material. In this case, since the charged particles E such as, for example, positive ions or electrons, or ultraviolet light may be suppressed from infiltrating into the processing chamber P side by the separation plate 15, the wafer processing with less damage is performed.

When the wafer W is rotated by 180 degrees by the wafer chuck 10 after a predetermined time has been elapsed, the neutral particles N are irradiated onto, for example, both side surfaces of the pattern 110 as illustrated in FIG. 4 so that a uniform processing is performed on the entire surface of the wafer W.

According to the exemplary embodiment described above, when the separation plate 15 formed with which the openings 15a inclined by the predetermined angle θ and the wafer W are rotated in relation to each other about the vertical axis as a rotational axis, the directivity of the neutral particles N irradiated from the separation plate 15 to the wafer W may be changed. Accordingly, even when the concave-convex pattern 110 is formed on the wafer W, the neutral particles N may be irradiated onto all the side surfaces of the pattern 110. As a result, the wafer W may be uniformly processed in the wafer plane using the neutral particles N.

In the exemplary embodiment described above, when the wafer chuck 10 is rotated after the neutral particles N are irradiated onto one surface of the pattern 110 for a predetermined time, the directivity of the neutral particles N irradiated onto the wafer W is changed in stepwise. For example, however, the wafer chuck 10 may be continuously rotated at a predetermined rotational speed to continuously change the directivity of the neutral particles N irradiated onto the wafer W.

Further, in the exemplary embodiment described above, when the wafer chuck 10 is rotated, the relative position between the wafer W and the separation plate 15 is changed in the rotational direction. For example, however, the separation plate 15 may be configured to be rotatable and the separation plate 15 may be rotated in a state where the wafer W is fixed, or both the wafer W and the separation plate 15 may be rotated.

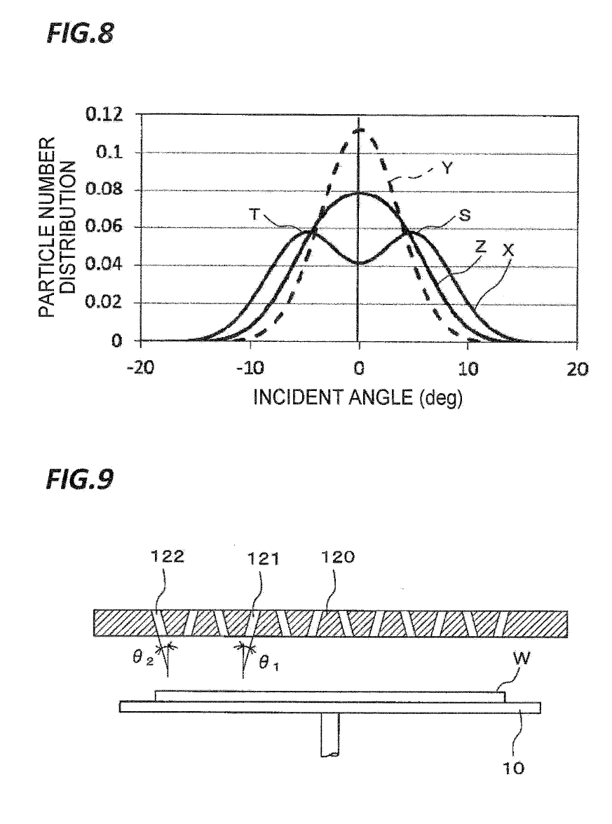

Various methods may be used as the method of irradiating the neutral particles N onto the entire surface of a wafer W having, for example a concave-convex pattern 110 formed thereon, without being limited to the contents of the present exemplary embodiment, Here, irradiating the neutral particles N onto the entire surface of the wafer W has the same meaning as irradiating the neutral particles N onto the wafer W from, for example, both sides of the surface of the concave-convex pattern 110 at approximately the same angle. More specifically, it means that the directivity of the neutral particles N is adjusted such that a plurality of peak values are distributed at positions located on both sides of the normal direction (a direction perpendicular to the surface of the wafer, that is, a position where the incident angle becomes 0 (zero) in FIG. 8) of the wafer W in the incident angle distribution of the neutral particles N during the wafer processing, for example, as illustrated with a curve X in FIG. 8, for example, at any position on the wafer W. Here, FIG. 8 illustrates a change in distribution of neutral particles for a case where the angle θ of the openings 15a is changed in the separation plate 15 in which the aspect ratio of the thickness T of the separation plate 15 and the diameter R of the openings 15a is about 10. In FIG. 8, the horizontal axis indicates an incident angle of the neutral particles N irradiated onto the wafer W, the vertical axis indicates a ratio of distribution of the neutral particles N incident onto the wafer W at the incident angle, and the curve X is obtained by combining the distribution of the neutral particles N obtained when the angle θ is set to +5 degrees and the distribution of the neutral particles obtained when the angle θ is set to −5 degrees. Accordingly, for example, when the neutral particles N are capable of being supplied to represent the incident angle distribution as illustrated by the curve X of FIG. 8, the method of irradiating the neutral particles N is considered as being fallen within the technical scope defined in the claims of the present disclosure.

In the meantime, as in the exemplary embodiment, in a case where the openings 15a are formed in the separation plate 15 by being inclined at the predetermined angle θ, the neutral particles N are irradiated onto the wafer W from only one direction, for example, as illustrated in FIG. 3, for example, in a state where a relative position between the wafer W and the separation plate 15 is fixed. Thus, the incident angle distribution becomes a portion in the curve X of FIG. 8 where the values of incident angles are positive, that is, a curve having a peak value S between the incident angle of about 0 degree and the incident angle of about 10 degrees. Also, when the wafer W and the separation plate 15 are rotated by 180 degrees in relation to each other and the neutral particles N are irradiated for the predetermined time after the predetermined time has been elapsed, the incident angle distribution of the neutral particles N after the wafer W and the separation plate 15 are relatively rotated by 180 degrees becomes a portion in the curve X of FIG. 8 where the values of incident angles are negative, that is, the curve having a peak value T between the incident angle of about 0 degree and the incident angle of about −10 degrees. Accordingly, it will be appreciated that the incident angle distribution on the wafer W before and after the wafer W is rotated by 180 degrees becomes a distribution where a plurality of peak values are distributed at positions on both sides of the normal direction, as represented by the curve X of FIG. 8. In the meantime, although the curve X of FIG. 8 represents an incident angle distribution that has a shape symmetrical with respect to the normal direction of the wafer W. However, the incident angle distribution does not necessarily have a symmetrical shape and at least the directivity of the neutral particles N may be adjusted such that the peaks appear at two locations on both sides of the normal direction. But, from the viewpoint of uniformity in the wafer plane, directivity of the neutral particles N may be adjusted such that peak values of the incident angle distribution are distributed in 2n-fold symmetry (n is an integer of 1 or more).

In the meantime, the aspect ratio between the thickness T of the separation plate 15 and the diameter R of the openings 15a is typically about 10 as described above and the neutral particles N passing through the openings 15a are irradiated with an inclination of, for example, ±5 degrees. Thus, even when the value of the angle θ of the openings 15a is 0 (zero), the incident angle distribution of the neutral particles N irradiated from the separation plate 15 will have an expansion of ±5 degrees on both sides of the normal direction of the wafer W in which the incident angle distribution is peak, as illustrated in FIG. 8 as the curve Y. However, in the incident angle distribution illustrated as the curve Y, since the neutral particles N are insufficiently irradiated onto the side surfaces of the pattern 110, the wafer W may not be processed uniformly in the wafer plane, unlike a case where the separation plate 15 according to the present exemplary embodiment is used. Further, the curve Z of FIG. 8 is formed by combining the distributions of the neutral particles N obtained when the angle θ is set to +3 degrees and −3 degrees. In this case, the distribution of neutral particles N has the peak in the normal direction of the wafer W and the wafer W may not be processed uniformly in the wafer plane, unlike a case where the separation plate 15 according to the present exemplary embodiment is used. From the results above, it can be confirmed that the angle θ of the openings 15a may be set to be about 4 degrees or more.

Further, the method of irradiating the neutral particles N by which the incident angle distribution as illustrated in FIG. 8 is obtained may utilize, for example, a separation plate 120 as illustrated in FIG. 9. The separation plate 120 includes first openings 121 formed to be inclined at the predetermined angle θ1 with respect to a direction perpendicular to the surface of the wafer W held on the wafer chuck 10 and second openings 122 formed line-symmetrically with respect to an axis perpendicular to the surface of the separation plate 120, and the first openings 121 and the second openings 122 are formed alternately to be adjacent to each other. When the separation plate 120 is formed in this way, the incident angle distribution of the neutral particles N irradiated onto the wafer W from the separation plate 120 has the shape as illustrated in FIG. 8, even if the wafer W and the separation plate 120 are not rotated relative to each other. In this case, since a component that rotates the wafer chuck 10 such as, for example, the chuck driving mechanism 21, becomes unnecessary, the configuration of the substrate processing apparatus 1 may be simplified. In the meantime, when the separation plate 120 illustrated in FIG. 8 is utilized, the separation plate 120 itself functions as the directivity adjusting mechanism which adjusts directivity of the neutral particles N. However, the separation plate 120 and the wafer W may, of course, be rotated in relation to each other.

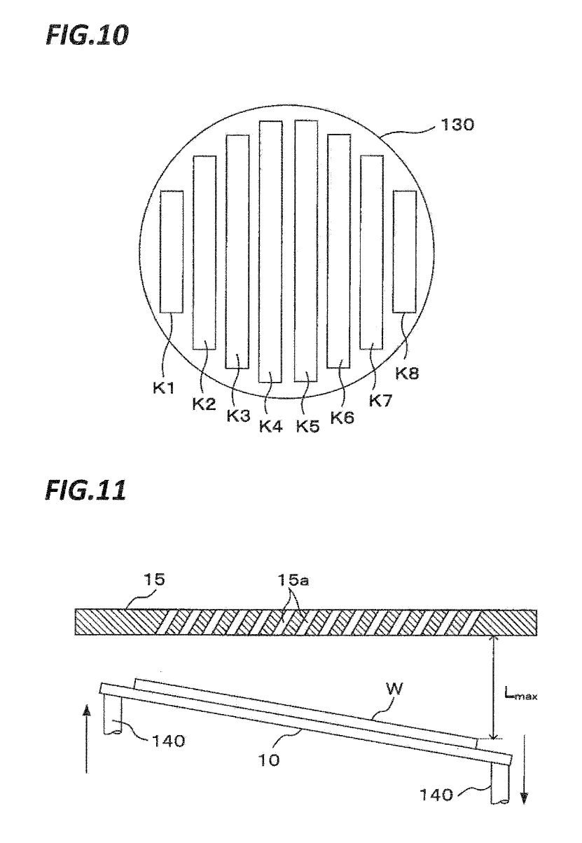

Further, an angle or direction of the openings 15a formed in the separation plate 15 is also not limited to, for example, the example illustrated in FIG. 2 or FIG. 9. For example, as illustrated in FIG. 10, the surface of the separation plate 130 may be divided into a plurality of areas K1 to K8 and the direction or angle of the openings in each of the areas K1 to K8 may be set to be different from the direction or angle of the openings in any other areas. In this case, for example, when the wafer W and the separation plate 130 are continuously rotated relative to each other, the incident angle distribution of the neutral particles N as illustrated in FIG. 8 may also be obtained.

In the meantime, in the exemplary embodiments described above, the directivity of the neutral particles N irradiated onto the wafer W is changed by rotating the wafer W and the separation plate 15 in relation to each other. However, the directivity of the neutral particles N may be changed by inclining the wafer W held on the wafer chuck 10 and the separation plate 15 in relation to each other. In this case, for example, a plurality of elevation mechanisms 140 may be provided for the wafer chuck 10 instead of the rotation axis 20 so that the wafer W may be inclined at any angle with respect to the separation plate 15, as illustrated in FIG. 11. In the meantime, in FIG. 11, the openings 15a are formed to be inclined at a predetermined angle θ . However, the openings 15a of the separation plate 15 may be formed along the vertical direction, from the viewpoint of changing the directivity of the neutral particles N irradiated onto the wafer W. However, it is preferable that the openings are formed to be inclined at the predetermined angle θ, from the viewpoint of generating the neutral particles N by causing the charged particles E to impinge onto the separation plate 15. Further, also in the present exemplary embodiment, the maximum distance Lmax between the wafer W and the separation plate 15 may be set not to exceed the mean free path in order to suitably irradiate the neutral particles N onto the wafer W.

In the meantime, the wafer chuck 10 inclined at the predetermined angle may be rotated by the elevation mechanism 140 and the directivity of the neutral particles N irradiated onto the wafer W may be adjusted using both the inclination and rotation of the wafer chuck 10.

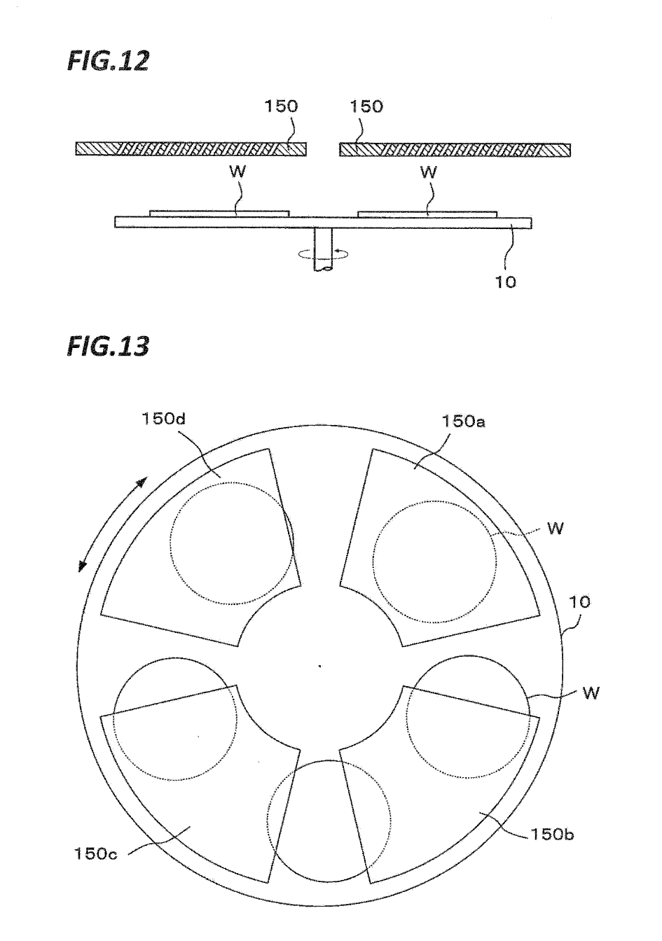

In the exemplary embodiments described above, the substrate processing apparatus 1 that processes a single wafer W is described by way of an example. However, the present disclosure may also be applied to, for example, a batch type substrate processing apparatus that processes a plurality of wafers W in a batch process. In this case, for example, the wafers W may be disposed on the wafer chuck 10 configured to hold a plurality of wafers W concentrically with the rotational axis of the wafer chuck 10, as illustrated in FIG. 12, and the separation plates 150 each formed in, for example, an arc shape, may be arranged concentrically with the rotational center of the wafer chuck 10. In the meantime, FIG. 13 is a plan view illustrating a situation where four separation plates 150a to 150d are provided. The directions or angles of the openings formed in the separation plates 150a to 150d may be formed such that for example, adjacent separation plates 150a and 150b make a pair. In this case, for example, when the wafers W are rotated by the wafer chuck 10 to pass through the underside of the separation plates 150a and 150b, the neutral particles N may be irradiated in the incident angle distribution as illustrated in FIG. 8. Although FIG. 13 illustrates four arc-shaped separation plates 150a to 150d, the shape, arrangement, or number of the separation plates 150a to 150d may be arbitrarily set.

In the meantime, each of the directions of the opening of the separation plates 150a to 150d may be changed by 90 degrees to be set and each wafer W may be caused to pass through below all the separation plates 150a to 150d so as to obtain the incident angle distribution as illustrated in FIG. 8.

In the meantime, in the exemplary embodiments described above, a wafer W having the concave-convex pattern 110 formed thereon as illustrated in FIG. 3 is utilized, but a pattern to be formed on the wafer W is not limited to that of the exemplary embodiments. For example, a wafer W having a planar film formed thereon may also be an object to be processed in the substrate processing apparatus 1 according to the present disclosure.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus that processes a substrate within a processing container by plasma, the substrate processing apparatus comprising:
a plasma generation source configured to generate the plasma within the processing container;
a substrate holding mechanism disposed to face the plasma generation source, and configured to hold the substrate within the processing container;
a separation plate disposed between the plasma generation source and the substrate holding mechanism and having a plurality of openings formed therein, the plurality of openings being configured to neutralize the plasma generated in the plasma generation source so as to form neutral particles, and to irradiate the neutral particles onto the substrate held on the substrate holding mechanism; and
a directivity adjusting mechanism configured to adjust directivity of the neutral particles irradiated onto the substrate such that a plurality of peak values of an incident angle distribution of the neutral particles on the substrate held by the substrate holding mechanism are distributed at positions which are deviated from a normal direction of the substrate and located on both sides of the normal direction,
wherein the openings of the separation plate include first openings inclined with respect to a direction perpendicular to a surface of the substrate held on the substrate holding mechanism by a predetermined angle, and second openings formed in linear symmetry with respect to an axis perpendicular to the surface of the separation plate, and
the first openings and the second openings are formed alternately to be adjacent to each other.

2. The substrate processing apparatus of claim 1, wherein the directivity adjusting mechanism adjusts the directivity of the neutral particles by rotating the substrate held on the substrate holding mechanism and the separation plate in relation to each other.

3. A substrate processing apparatus that processes a substrate within a processing container by plasma, the substrate processing apparatus comprising:
a plasma generation source configured to generate the plasma within the processing container;
a substrate holding mechanism disposed to face the plasma generation source, and configured to hold the substrate within the processing container;
a separation plate disposed between the plasma generation source and the substrate holding mechanism and having a plurality of openings formed therein, the plurality of openings being configured to neutralize the plasma generated in the plasma generation source so as to form neutral particles, and to irradiate the neutral particles onto the substrate held on the substrate holding mechanism; and
a directivity adjusting mechanism configured to adjust directivity of the neutral particles irradiated onto the substrate such that a plurality of peak values of an incident angle distribution of the neutral particles on the substrate held by the substrate holding mechanism are distributed at positions which are deviated from a normal direction of the substrate and located on both sides of the normal direction,
wherein the separation plate is divided into a plurality of sections and the openings are formed in each section to be inclined with respect to the vertical direction by a predetermined angle, and
the directivity adjusting mechanism adjusts the directivity of the neutral particles by rotating the substrate held on the substrate holding mechanism and the separation plate in relation to each other.

4. The substrate processing apparatus of claim 1, wherein the directivity adjusting mechanism adjusts the directivity of the neutral particles such that the peak values in the incident angle distribution of the neutral particles are distributed in 2n-fold symmetry (n is an integer of 1 or more).

5. The substrate processing apparatus of claim 2, wherein the directivity adjusting mechanism adjusts the directivity of the neutral particles such that the peak values in the incident angle distribution of the neutral particles are distributed in 2n-fold symmetry (n is an integer of 1 or more).

6. The substrate processing apparatus of claim 3, wherein the directivity adjusting mechanism adjusts the directivity of the neutral particles such that the peak values in the incident angle distribution of the neutral particles are distributed in 2n-fold symmetry (n is an integer of 1 or more).
